(19) United States
(12) Patent Application Publication
(10) Pub. No.: US 2025/0309208 A1
(43) Pub. Date: Oct. 2, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Jia LIU, Yokohama (JP); Toshihiro TSUJIMURA, Tokyo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/819,004

(22) Filed: Aug. 29, 2024

(30) Foreign Application Priority Data
Apr. 2, 2024 (JP) 2024-059536

(51) Int. Cl. H01L 25/16; H01L 31/12; H01L 31/153

(52) U.S. Cl. CPC H01L 25/167; H10F 55/155; H10F 55/18

(57) ABSTRACT

According to one embodiment, a semiconductor device includes: a substrate including a first surface extending in a first direction and a second direction; a first transistor; a light receiver; a light emitter provided on the light receiver; an input terminal provided on the first surface of the substrate; a first conductor configured to electrically couple a source electrode of the first transistor and a first electrode of the light receiver; a second conductor configured to electrically couple a gate electrode of the first transistor and a second electrode of the light receiver; and a third conductor configured to couple a third electrode of the light emitter and the input terminal, wherein the light emitter and the input terminal are provided at positions overlapping with each other in a third direction, and the third conductor is provided inside the substrate.

### CROSS-REFERENCE TO RELATED APPLICATIONS

This application is based upon and claims the benefit of priority from Japanese Patent Application No. 2024-059536, filed Apr. 2, 2024, the entire contents of which are incorporated herein by reference.

### FIELD

Embodiments described herein relate generally to a semiconductor device.

### BACKGROUND

A photo relay device is known as a semiconductor device. The photo relay device is a semiconductor relay device including a light emitter and a light receiver. The photo relay device is a contactless relay, and is used for transmission of an AC signal or a DC signal.

### BRIEF DESCRIPTION OF DRAWINGS

FIG. 1 is a circuit diagram showing an example of a circuit configuration of a photo relay device according to a first embodiment.

FIG. 2 is a perspective view showing an example of an overall structure of the photo relay device according to the first embodiment.

FIG. 3 is a plan view showing an example of a planar layout of various elements included in the photo relay device according to the first embodiment.

FIG. 4 is a cross-sectional view taken along the line IV-IV of FIG. 3, showing an example of a cross-sectional structure of the photo relay device according to the first embodiment.

FIG. 5 is a cross-sectional view taken along the line V-V of FIG. 3, showing an example of a cross-sectional structure of the photo relay device according to the first embodiment.

FIG. 6 is a cross-sectional view taken along the line VI-VI of FIG. 3, showing an example of a cross-sectional structure of the photo relay device according to the first embodiment.

FIG. 7 is a cross-sectional view taken along the line VII-VII of FIG. 3, showing an example of a cross-sectional structure of the photo relay device according to the first embodiment.

FIG. 8 is a cross-sectional view showing an example of a cross-sectional structure in the process of manufacturing the photo relay device according to the first embodiment.

FIG. 9 is a cross-sectional view showing an example of a cross-sectional structure in the process of manufacturing the photo relay device according to the first embodiment.

FIG. 10 is a cross-sectional view showing an example of a cross-sectional structure in the process of manufacturing the photo relay device according to the first embodiment.

FIG. 11 is a cross-sectional view showing an example of a cross-sectional structure in the process of manufacturing the photo relay device according to the first embodiment.

FIG. 12 is a cross-sectional view showing an example of a cross-sectional structure in the process of manufacturing the photo relay device according to the first embodiment.

FIG. 13 is a perspective view showing an example of an overall structure of a photo relay device according to a second embodiment.

FIG. 14 is a cross-sectional view showing an example of a cross-sectional structure of the photo relay device according to the second embodiment.

### DETAILED DESCRIPTION

In general, according to one embodiment, a semiconductor device includes: a substrate including a first surface extending in a first direction and a second direction; a first transistor; a light receiver; a light emitter provided on the light receiver; an input terminal provided on the first surface of the substrate; a first conductor configured to electrically couple a source electrode of the first transistor and a first electrode of the light receiver; a second conductor configured to electrically couple a gate electrode of the first transistor and a second electrode of the light receiver; and a third conductor configured to couple a third electrode of the light emitter and the input terminal, wherein the light emitter and the input terminal are provided at positions overlapping with each other in a third direction intersecting the first direction and the second direction, and the third conductor is provided inside the substrate.

Hereinafter, embodiments will be described with reference to the drawings. Note that, in the following description, components having substantially the same functions and configurations are denoted by the same reference numerals.

In the following description, a first element being “coupled” to another second element encompasses a case where the first element is coupled to the second element either indirectly via an intermediate element that is always or selectively conductive, or directly without an intermediate element.

A first embodiment will be described. Hereinafter, a photo relay device will be described as an example of a semiconductor device according to the first embodiment.

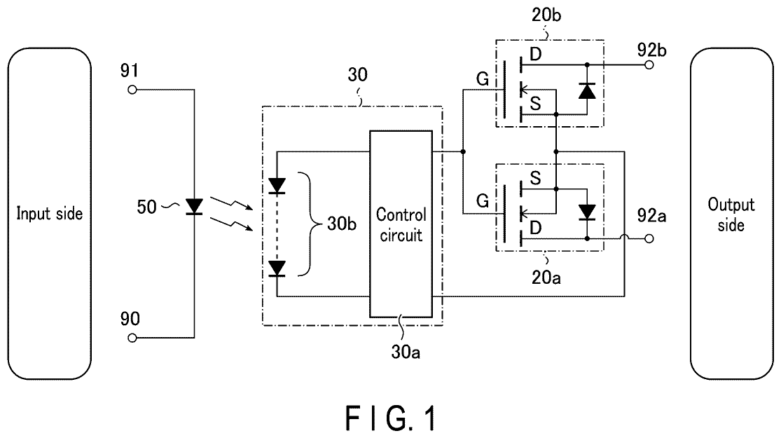

FIG. 1 is a circuit diagram showing an example of a circuit configuration of a photo relay device according to the first embodiment. An example of a circuit configuration of a photo relay device 1 according to the first embodiment will be described with reference to FIG. 1.

As shown in FIG. 1, the photo relay device 1 includes two transistors 20a and 20b, a light receiver 30, a light emitter 50, input terminals 90 and 91, and output terminals 92a and 92b.

The transistors 20a and 20b are, for example, metal oxide semiconductor field effect transistors (MOSFETs). Hereinafter, a case where the transistors 20a and 20b are MOSFETs (MOSFETs 20a and 20b) will be described.

The MOSFETs 20a and 20b are, for example, enhancement type n-channel MOSFETs. The MOSFETs 20a and 20b are used to control signals to be transmitted. Drain terminals of the MOSFETs 20a and 20b are coupled to the output terminals 92a and 92b, respectively. Source terminals of the MOSFETs 20a and 20b are commonly coupled to a cathode of the light receiver 30. Gate terminals of the MOSFETs 20a and 20b are commonly coupled to an anode of the light receiver 30.

The light receiver 30 is, for example, a photo diode array (PDA) including a control circuit 30a and several to several tens of photodiodes 30b coupled in series. Both ends of the photodiodes 30b coupled in series are coupled to the control circuit 30a. The control circuit 30a controls the MOSFETs 20a and 20b using voltages applied from the photodiodes 30b as a power supply voltage. Note that the light receiver 30 may be a phototransistor or the like. Hereinafter, a case where the light receiver 30 is the PDA will be described.

The light emitter 50 is, for example, a light emitting diode (LED). The light emitter 50 is coupled to the input terminals 90 and 91. Signals transmitted via the photo relay device 1 are input to the input terminals 90 and 91.

If a sufficient potential difference is generated between the input terminals 90 and 91, the light emitter 50 is turned on (lit state). At this time, the light receiver 30 receives light from the light emitter 50 and generates a voltage of, for example, 7 V to more than a dozen V. As a result, the MOSFETs 20a and 20b are turned on, and the output terminals 92a and 92b are coupled to each other. On the other hand, if the potential difference between the input terminals 90 and 91 decreases and the light emitter 50 is turned off (unlit state), the MOSFETs 20a and 20b are turned off, and the output terminals 92a and 92b are insulated from each other.

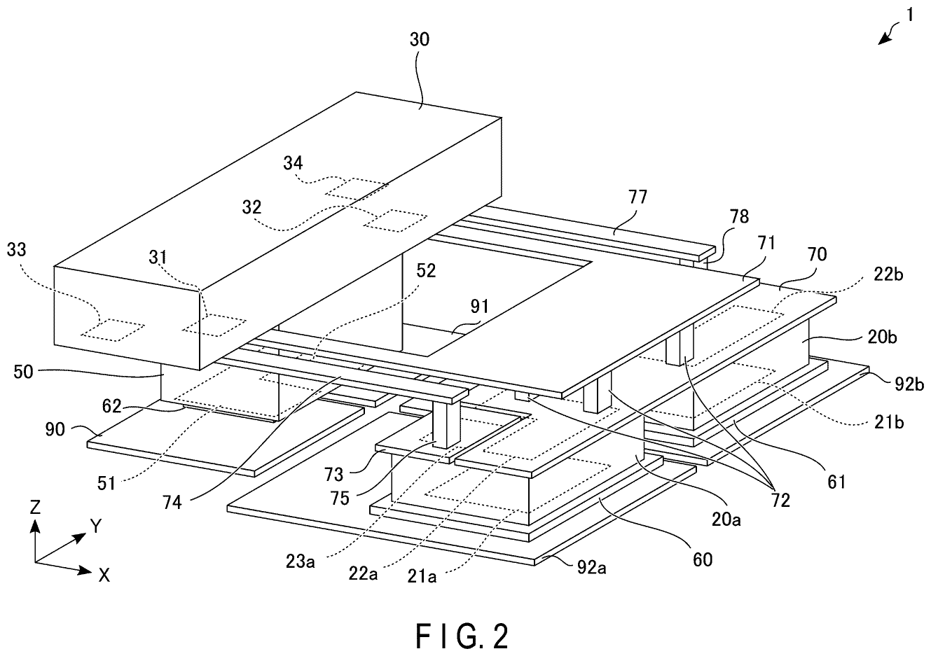

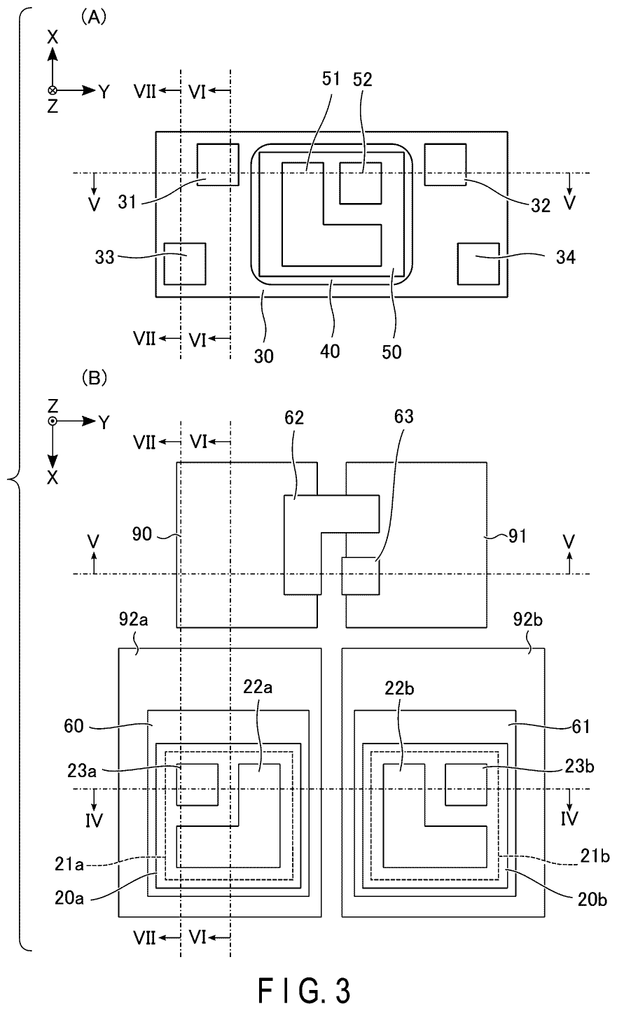

A structure of the photo relay device according to the first embodiment will be described with reference to FIGS. 2 and 3. FIG. 2 is a perspective view showing an example of an overall structure of the photo relay device according to the first embodiment. FIG. 3 is a plan view showing an example of a planar layout of various elements included in the photo relay device according to the first embodiment. Note that, in FIG. 3, some conductors are omitted. As shown in FIGS. 2 and 3, the photo relay device 1 further includes an adhesive layer 40 and conductors 60, 61, 62, 63, 70, 71, 72, 73, 74, 75, 77, and 78.

The MOSFETs 20a and 20b have, for example, a rectangular shape in the plan view, and are provided such that sides thereof face each other. Hereinafter, a direction in which the MOSFETs 20a and 20b are arranged is defined as a Y direction. In addition, the light emitter 50 is provided side by side with the MOSFETs 20a and 20b in a direction intersecting the Y direction. Hereinafter, a direction in which the light emitter 50 and the MOSFETs 20a and 20b are arranged is defined as an X direction. The light receiver 30 is provided up and down with the light emitter 50 in a direction intersecting the X direction and the Y direction. Hereinafter, a direction in which the light receiver 30 and the light emitter 50 are arranged is defined as a Z direction, a direction in which the light receiver 30 is provided as viewed from the light emitter 50 is defined as an upward direction, and a direction in which the light emitter 50 is provided as viewed from the light receiver 30 is defined as a downward direction. That is, the plan view shown in a part (A) of FIG. 3 corresponds to the planar layout of the light receiver 30, the adhesive layer 40, and the light emitter 50 in a case where the photo relay device 1 is viewed from bottom side in the upward direction. The plan view shown in a part (B) of FIG. 3 corresponds to the planar layout of the MOSFETs 20a and 20b, the conductors 60, 61, 62, and 63, the input terminals 90 and 91, and the output terminals 92a and 92b in a case where the photo relay device 1 is viewed from top side in the downward direction.

The MOSFET 20a includes electrodes 21a, 22a, and 23a. The electrode 21a is provided on a bottom surface of the MOSFET 20a and functions as a drain electrode of the MOSFET 20a. The electrode 22a is provided on a top surface of the MOSFET 20a and functions as a source electrode of the MOSFET 20a. The electrode 23a is provided on the top surface of the MOSFET 20a and functions as a gate electrode of the MOSFET 20a.

The MOSFET 20b includes electrodes 21b, 22b, and 23b. The electrode 21b is provided on a bottom surface of the MOSFET 20b and functions as a drain electrode of the MOSFET 20b. The electrode 22b is provided on a top surface of the MOSFET 20b and functions as a source electrode of the MOSFET 20b. The electrode 23b is provided on the top surface of the MOSFET 20b and functions as a gate electrode of the MOSFET 20b.

In the examples shown in FIGS. 2 and 3, the electrodes 22a and 23a of the MOSFET 20a and the electrodes 22b and 23b of the MOSFET 20b are disposed so as to be plane-symmetric with respect to an XZ plane. The electrode 23a is provided at a position along two sides of a side extending in the X direction on a side far from the MOSFET 20b and a side extending in the Y direction on a side close to the light receiver 30 on the top surface of the MOSFET 20a. The electrode 23b is provided at a position along two sides of a side extending in the X direction on a side far from the MOSFET 20a and a side extending in the Y direction on a side close to the light receiver 30 on the top surface of the MOSFET 20b.

The light receiver 30 further includes a light receiving surface and electrodes 31, 32, 33, and 34. The light receiving surface of the light receiver 30 is provided on a bottom surface of the light receiver 30. That is, the light receiving surface of the light receiver 30 faces the downward side on which the light emitter 50 is disposed. The electrodes 31, 32, 33, and 34 are provided on the bottom surface of the light receiver 30. The electrodes 31 and 32 are provided so as to sandwich the light receiving surface of the light receiver 30 in the Y direction. For example, the electrodes 31 and 32 are electrically coupled by interconnects (not shown) provided in the light receiver 30. The electrodes 33 and 34 are provided so as to sandwich the light receiving surface of the light receiver 30 in the Y direction. For example, the electrodes 33 and 34 are electrically coupled by interconnects (not shown) provided in the light receiver 30.

The light emitter 50 is provided on the bottom surface of the light receiver 30 with the adhesive layer 40 interposed therebetween. Note that an insulating material having a light transmitting property is used for the adhesive layer 40. The light emitter 50 includes a light emitting surface and electrodes 51 and 52. The light emitting surface of the light emitter 50 is provided on the top surface of the light emitter 50. That is, the light emitting surface of the light emitter 50 faces the side (upward direction) on which the light receiver 30 is disposed. The light emitting surface of the light emitter 50 faces the light receiving surface of the light receiver 30 via the adhesive layer 40. The electrodes 51 and 52 are provided on the bottom surface of the light emitter 50. One of the electrodes 51 and 52 is an anode electrode of the light emitter 50, and the other is a cathode electrode of the light emitter 50. In the examples shown in FIGS. 2 and 3, the electrode 52 corresponds to the anode electrode of the light emitter 50, and the electrode 51 corresponds to the cathode electrode of the light emitter 50.

The conductors 60 and 61 are provided below the MOSFETs 20a and 20b, respectively. The conductor 60 is in contact with the electrode 21a of the MOSFET 20a. The conductor 61 is in contact with the electrode 21b of the MOSFET 20b.

The conductors 62 and 63 are provided below the light emitter 50 at substantially the same positions as the conductors 60 and 61 in the Z direction. The conductor 62 is in contact with the electrode 51. The conductor 63 is in contact with the electrode 52. Note that the shapes of the conductors 62 and 63 are formed to correspond to the shapes of the electrodes 51 and 52.

The conductors 70, 71, 72, 73, 74, 75, 77, and 78 are, for example, interconnect structures provided inside a substrate. The conductor 70 has a flat plate shape extending on the XY plane. The conductor 70 is in contact with the electrode 22a of the MOSFET 20a and the electrode 22b of the MOSFET 20b to couple them to each other. The conductor 70 and the electrodes 22a and 22b are coupled to one another over as large an area as possible so as to widely cover a portion of the top surfaces of the MOSFETs 20a and 20b excluding the electrodes 23a and 23b. The conductor 71 has a U-shaped flat plate shape extending on the XY plane including two portions extending in the X direction, and is provided so as to sandwich the light emitter 50 in the Y direction. The conductor 71 is in contact with the electrodes 31 and 32 of the light receiver 30 to couple them to each other. The conductor 72 extends in the Z direction and couples the conductors 70 and 71. That is, the electrode 22a of the MOSFET 20a, the electrode 22b of the MOSFET 20b, and the electrodes 31 and 32 of the light receiver 30 are coupled to each other via the conductors 70, 71, and 72. The conductor 73 has a flat plate shape extending on the XY plane. The conductor 73 is in contact with the electrode 23a of the MOSFET 20a. The conductor 74 has a flat plate shape extending in the X direction. The conductor 74 is in contact with the electrode 33 of the light receiver 30. The conductor 75 extends in the Z direction and couples the conductors 73 and 74. That is, the electrode 23a of the MOSFET 20a and the electrode 33 of the light receiver 30 are coupled via the conductors 73, 74, and 75. The conductor 77 has a flat plate shape extending in the X direction. The conductor 77 is in contact with the electrode 34 of the light receiver 30. The conductor 78 extends in the Z direction and couples the conductor 77 and a conductor (hereinafter, referred to as a conductor 76) having a flat plate shape extending on an XY plane not shown and in contact with the electrode 23b of the MOSFET 20b. That is, the electrode 23b of the MOSFET 20b and the electrode 34 of the light receiver 30 are coupled via the conductors 76, 77, and 78.

The input terminals 90 and 91 are provided below the conductors 62 and 63, respectively. That is, the input terminals 90 and 91 are provided at positions overlapping the light emitter 50 in the Z direction. The input terminal 90 is coupled to the conductor 62 via a conductor (not shown). The input terminal 91 is coupled to the conductor 63 via a conductor (not shown). The input terminals 90 and 91 are coupled to a signal source (not shown) provided outside.

The output terminals 92a and 92b are provided below the conductors 60 and 61, respectively. The output terminal 92a is coupled to the conductor 60 via a conductor (not shown). The output terminal 92b is coupled to the conductor 61 via a conductor (not shown). The output terminals 92a and 92b are coupled to a circuit (not shown) or the like provided outside. As described above, a signal is transmitted from a signal source to a circuit or the like via the photo relay device 1.

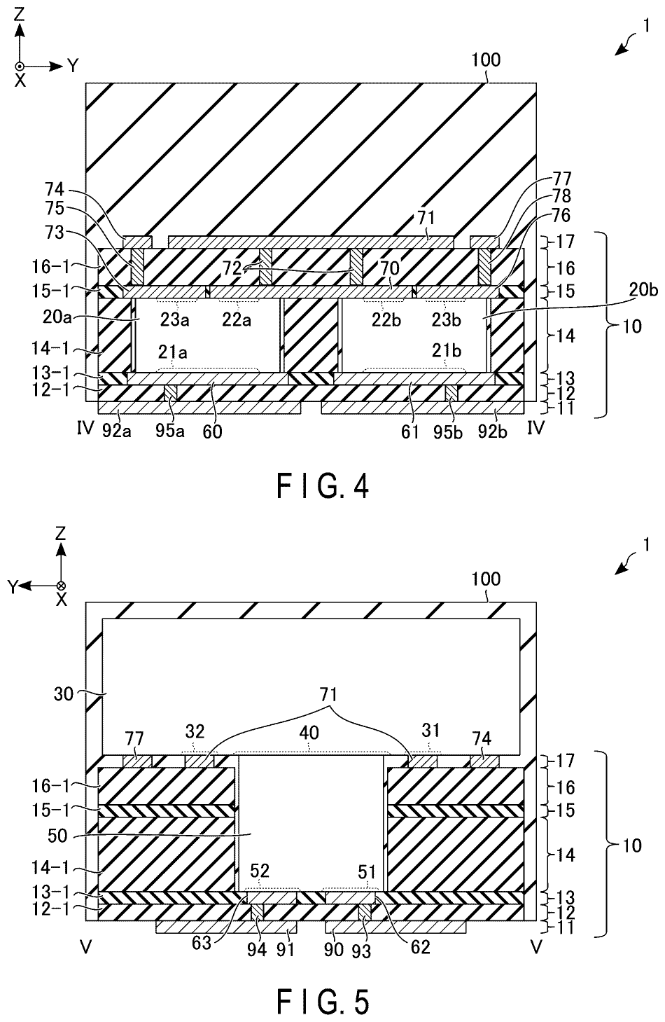

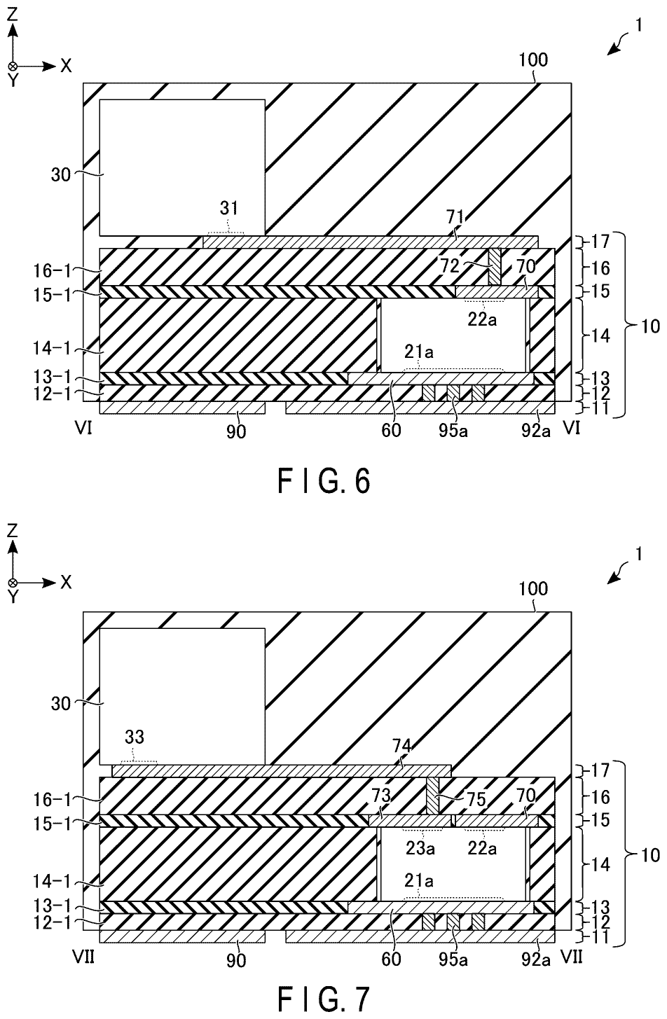

A cross-sectional structure of the photo relay device according to the first embodiment will be described with reference to FIGS. 4 to 7. FIGS. 4 to 7 are cross-sectional views taken along the lines IV-IV, V-V, VI-VI, and VII-VII of FIG. 3, respectively, showing an example of the cross-sectional structure of the photo relay device according to the first embodiment. FIG. 4 corresponds to a YZ cross section of a portion including the conductors 60, 61, 75, and 78 and a part of the conductor 72 of the photo relay device 1. FIG. 5 corresponds to a YZ cross section of a portion including the conductors 62, 63, 71, 74, and 77 of the photo relay device 1. FIG. 6 corresponds to an XZ cross section of a portion including the conductor 71 of the photo relay device 1. FIG. 7 corresponds to an XZ cross section of a portion including the conductor 74 of the photo relay device 1.

First, a configuration of the photo relay device 1 will be described with reference to FIGS. 4 to 7. As shown in FIGS. 4 to 7, the photo relay device 1 further includes a substrate 10, conductors 93, 94, 95a, and 95b, and a sealing resin 100.

The substrate 10 is, for example, a flexible printed circuit (FPC) using polyimide, a resin substrate, a silicon substrate, or a polyimide substrate. The substrate 10 includes interconnect layers 11, 13, 15, and 17 and insulator layers 12, 14, and 16. The substrate 10 includes, for example, a seven-layer structure in which the interconnect layer 11, the insulator layer 12, the interconnect layer 13, the insulator layer 14, the interconnect layer 15, the insulator layer 16, and the interconnect layer 17 are stacked sequentially in the upward direction. The MOSFETs 20a and 20b are disposed in a layer corresponding to the insulator layer 14 of the substrate 10 so as to be embedded therein. That is, the MOSFETs 20a and 20b are provided at positions intersecting the substrate 10 on the XY plane. In addition, the substrate 10 has an opening that is a hole penetrating the interconnect layers 15 and 17 and the insulator layers 14 and 16, and reaching the interconnect layer 13. The light emitter 50 is disposed in the opening of the substrate 10. That is, the light emitter 50 is provided at a position intersecting the substrate 10 on the XY plane. The substrate 10 includes a plurality of conductors. The conductors appropriately couple terminals provided in contact with the substrate 10 as substrate interconnects.

The conductors 93, 94, 95a, and 95b are, for example, interconnect structures provided inside the substrate. The conductor 93 extends in the Z direction and couples the conductor 62 and the input terminal 90. The conductor 94 extends in the Z direction and couples the conductor 63 and the input terminal 91. The conductor 95a extends in the Z direction and couples the conductor 60 and the output terminal 92a. The conductor 95b extends in the Z direction and couples the conductor 61 and the output terminal 92b. Note that, in the examples of FIGS. 6 and 7, three conductors 95a are provided, but one or more conductors 95a may be provided. Similarly, one or more conductors 95b may be provided.

The sealing resin 100 is, for example, a mold resin having a light shielding property. The sealing resin 100 covers the MOSFETs 20a and 20b, the light receiver 30, and the light emitter 50 to protect them from physical or electrical disturbance.

Next, a configuration for coupling the MOSFETs 20a and 20b and the output terminals 92a and 92b will be described with reference to FIG. 4.

The interconnect layer 11 includes output terminals 92a and 92b. The insulator layer 12 includes conductors 95a and 95b and an insulator 12-1. The interconnect layer 13 includes conductors 60 and 61 and an insulator 13-1. The insulator layer 14 includes an insulator 14-1. The conductor 95a functions as a via extending in the Z direction inside the insulator 12-1 so as to couple a top surface of the output terminal 92a and a bottom surface of the conductor 60. The conductor 95b functions as a via extending in the Z direction inside the insulator 12-1 so as to couple a top surface of the output terminal 92b and a bottom surface of the conductor 61. The insulator 13-1 insulates the conductor 60 and the conductor 61 from each other.

With the above configuration, the MOSFETs 20a and 20b are coupled to the output terminals 92a and 92b.

Next, a configuration for coupling the light emitter 50 and the input terminals 90 and 91 will be described with reference to FIG. 5.

The interconnect layer 11 further includes input terminals 90 and 91. The insulator layer 12 further includes conductors 93 and 94. The interconnect layer 13 further includes conductors 62 and 63. The conductor 93 functions as a via extending in the Z direction inside the insulator 12-1 so as to couple the top surface of the input terminal 90 and the bottom surface of the conductor 62. The conductor 94 functions as a via extending in the Z direction inside the insulator 12-1 so as to couple the top surface of the input terminal 91 and the bottom surface of the conductor 63. The insulator 13-1 insulates the conductor 62, the conductor 63, and the conductors 60 and 61 from one another.

With the above configuration, the light emitter 50 and the input terminals 90 and 91 are coupled to, respectively.

Next, a configuration for coupling the source terminal of the MOSFET 20a, the source terminal of the MOSFET 20b, and the electrodes 31 and 32 of the light receiver 30 will be described with reference to FIGS. 4 and 6.

The interconnect layer 15 includes a conductor 70 and an insulator 15-1. The insulator layer 16 includes a conductor 72 and an insulator 16-1. The interconnect layer 17 includes a conductor 71. The conductor 72 functions as a via extending in the Z direction inside the insulator 16-1 so as to couple the top surface of the conductor 70 and the bottom surface of the conductor 71. Although two conductors 72 are shown in FIG. 4, the number of conductors 72 may be one or more. The source terminal of the MOSFET 20a, the source terminal of the MOSFET 20b, and the electrodes 31 and 32 of the light receiver 30 are coupled to one another via the conductors 70, 71, and 72.

Next, a configuration for coupling the gate terminal of the MOSFET 20a and the electrode 33 of the light receiver 30 will be described with reference to FIGS. 4 and 7.

The interconnect layer 15 further includes a conductor 73. The insulator layer 16 further includes a conductor 75. The interconnect layer 17 further includes a conductor 74. The insulator 15-1 insulates the conductor 73 from the conductor 70 each other. The conductor 75 functions as a via extending in the Z direction inside the insulator 16-1 so as to couple the top surface of the conductor 73 and the bottom surface of the conductor 74. The gate terminal of the MOSFET 20a and the electrode 33 of the light receiver 30 are coupled via the conductors 73, 74, and 75.

Although not shown, the gate terminal of the MOSFET 20b and the electrode 34 of the light receiver 30 are also coupled in a configuration similar to the configuration in which the gate terminal of the MOSFET 20a and the electrode 33 of the light receiver 30 are coupled. Specifically, both are coupled via the conductors 76, 77, and 78. As shown in FIG. 4, the interconnect layer 15 further includes a conductor 76. The insulator layer 16 further includes a conductor 78. The interconnect layer 17 further includes a conductor 77. The conductor 78 functions as a via extending in the Z direction inside the insulator 16-1 so as to couple the top surface of the conductor 76 and the bottom surface of the conductor 77. The insulator 15-1 insulates the conductor 76 from the conductors 70 and 73 one another.

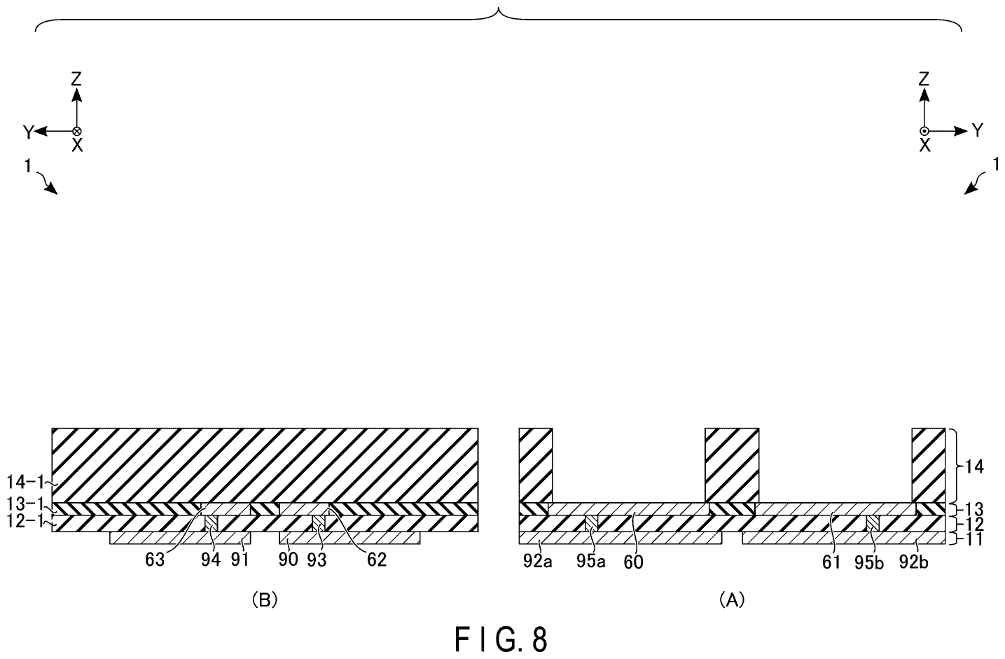

A method for manufacturing the photo relay device according to the first embodiment will be described with reference to FIGS. 8 to 12. FIGS. 8 to 12 show an example of a cross-sectional structure in the process of manufacturing the photo relay device according to the first embodiment. The cross-sectional structure shown in FIGS. 8 to 12 shows a portion (A) in which the MOSFETs corresponding to FIG. 4 are disposed and a portion (B) in which the light receiver and the light emitter corresponding to FIG. 5 are disposed.

First, the MOSFETs 20a and 20b, the light receiver 30, and the light emitter 50 are individually formed. The light receiver 30 and the light emitter 50 are joined via the adhesive layer 40 such that the light receiving surface of the light receiver 30 and the light emitting surface of the light emitter 50 face each other. As the substrate 10, the interconnect layer 11, the insulator layer 12, the interconnect layer 13, and the insulator layer 14 are stacked in this order.

Next, as shown in the portion (A) of FIG. 8, two holes penetrating the insulator layer 14 are provided in a portion of the substrate 10 corresponding to a place where the MOSFETs 20a and 20b are disposed, for example, by laser processing. The conductors 60 and 61 are exposed by the laser processing.

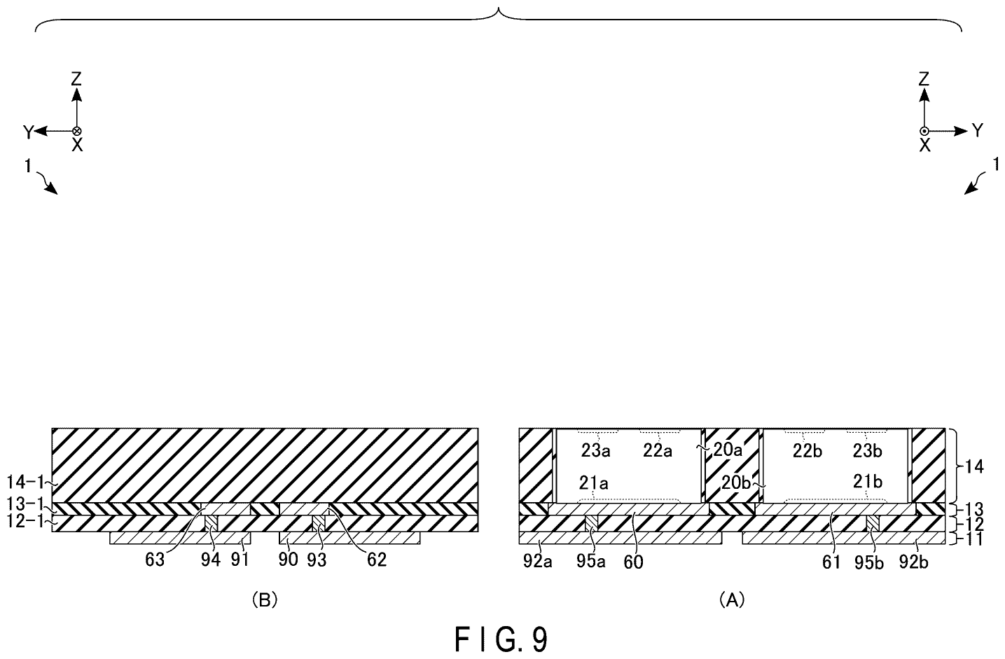

Next, as shown in the portion (A) of FIG. 9, the electrode 21a of the MOSFET 20a is bonded onto the top surface of the conductor 60. The electrode 21b of the MOSFET 20b is bonded onto the top surface of the conductor 61. As a result, the MOSFETs 20a and 20b are supported by the substrate 10. A gap between the substrate 10 and the MOSFETs 20a and 20b is filled with a resin.

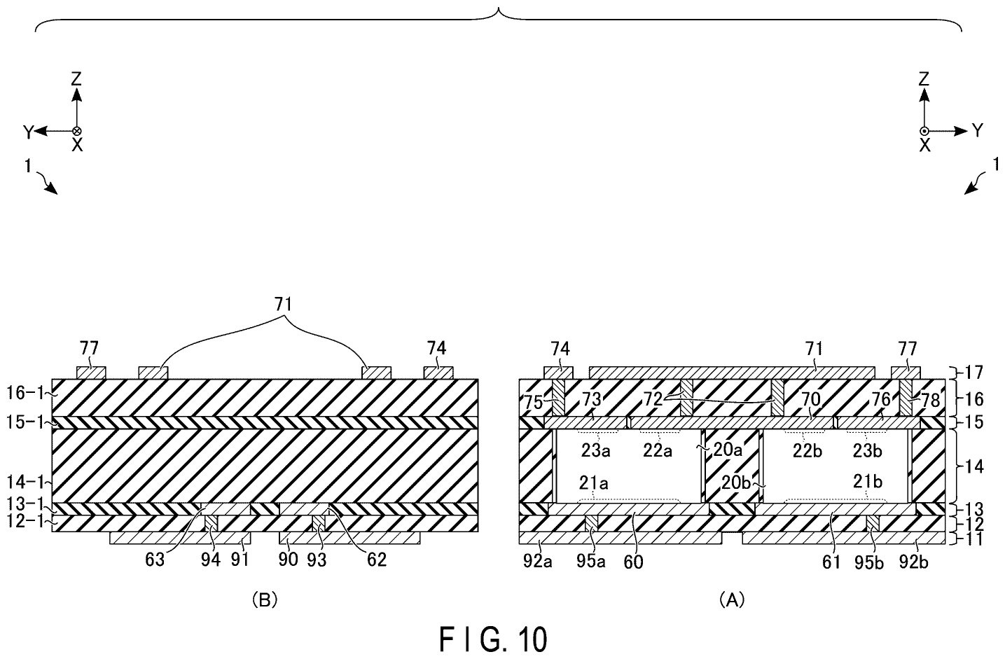

Next, as shown in FIG. 10, the interconnect layer 15, the insulator layer 16, and the interconnect layer 17 are provided in this order on the insulator layer 14 and the top surfaces of the MOSFETs 20a and 20b. Specifically, in the portion (A), the electrode 22a of the MOSFET 20a and the electrode 22b of the MOSFET 20b are joined to the conductor 70 of the interconnect layer 15. The electrode 23a of the MOSFET 20a is joined to the conductor 73 of the interconnect layer 15. The electrode 23b of the MOSFET 20b is joined to the conductor 76 of the interconnect layer 15.

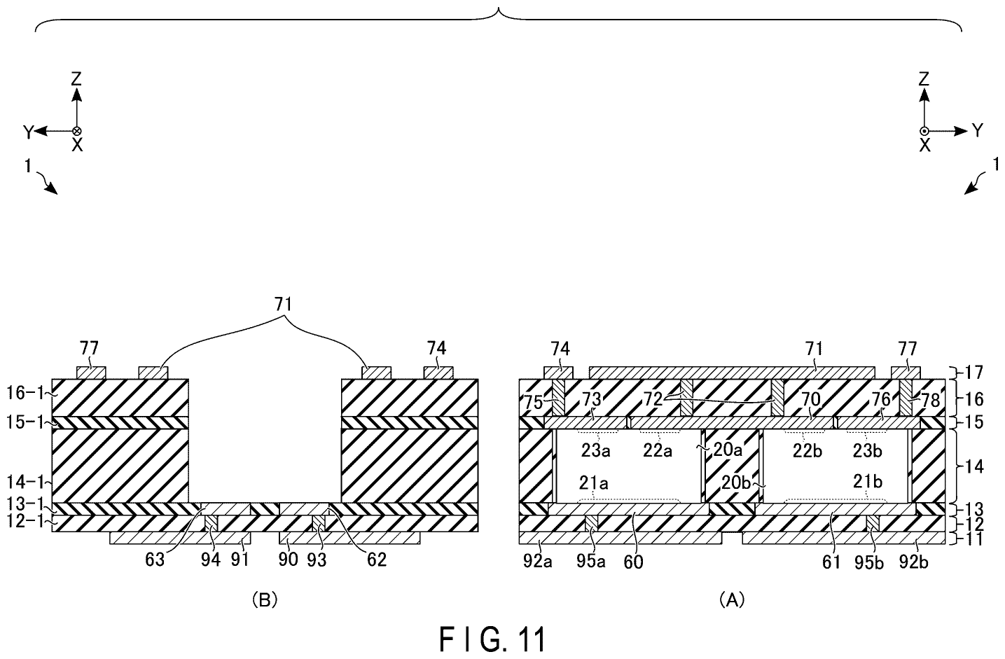

Next, as shown in the portion (B) of FIG. 11, an opening penetrating the insulator layers 14 and 16 and the interconnect layers 15 and 17 is formed in a portion of the substrate 10 corresponding to a place where the light emitter 50 is disposed, for example, by the laser processing. The conductors 62 and 63 are exposed by the laser processing.

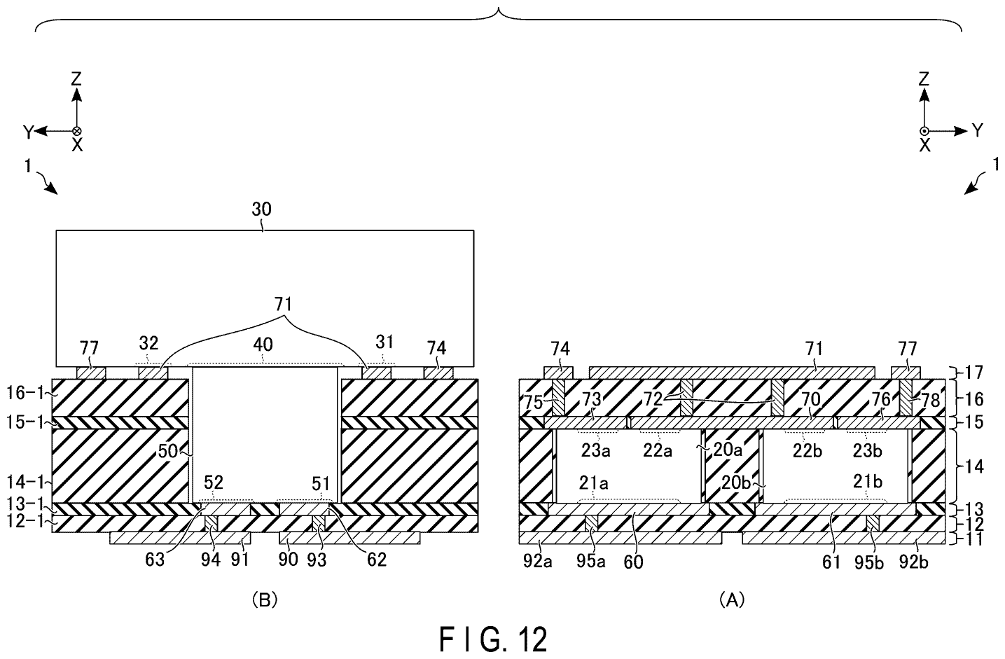

Next, as shown in the portion (B) of FIG. 12, the light receiver 30 and the light emitter 50 joined via the adhesive layer 40 are provided to the opening penetrating the insulator layers 14 and 16 and the interconnect layers 15 and 17, and the top surface of the substrate 10. At this time, the light emitter 50 is provided on the top surface of the interconnect layer 13 within the opening so as to correspond thereto, and the light receiver 30 is provided on the top surface of the interconnect layer 17 so as to correspond thereto. Specifically, the electrodes 51 and 52 of the light emitter 50 are joined to the conductors 62 and 63 of the interconnect layer 13, respectively. The electrodes 31 and 32 of the light receiver 30 are joined to the conductor 71 of the interconnect layer 17. Although not shown, the electrodes 33 and 34 of the light receiver 30 are joined to the conductors 74 and 77 of the interconnect layer 17, respectively.

Finally, a portion excluding the lower portion of the structure obtained by the above-described steps is sealed with the sealing resin 100. In this way, the photo relay device 1 is manufactured.

The configuration according to the first embodiment can improve transmission characteristics of a signal to be transmitted using the photo relay device 1. In addition, downsizing and thinning of the photo relay device can be achieved. These will be described in detail below.

In the configuration according to the first embodiment, the respective electrodes of the MOSFETs 20a and 20b, the light receiver 30, the light emitter 50, the input terminals 90 and 91, and the output terminals 92a and 92b are coupled by the substrate interconnects. Therefore, a length of an open stub can be reduced as compared with the case of using a wire as the interconnect. As a result, since a resonance frequency of the signal shifts to the high frequency side, a communication band increases, and the transmission characteristics of the signal can be improved.

In the configuration according to the first embodiment, the electrodes 31 to 34 of the light receiver 30 are directly coupled to the conductors 71, 74, and 77 on the substrate 10. Thus, a mounting pad for mounting the light receiver 30 on the substrate 10 becomes unnecessary. For this reason, no coupling capacitance is generated between the mounting pad and each of the input terminals 90 and 91 and the output terminals 92a and 92b. Therefore, it is possible to suppress deterioration of signal transmission characteristics in a high frequency band due to coupling capacitances.

In addition, in the configuration according to the first embodiment, the electrode 22a of the MOSFET 20a and the electrode 22b of the MOSFET 20b are coupled via the conductor 70 having as large an area as possible. For this reason, the impedance of a circuit coupling the source electrodes of the MOSFETs 20a and 20b can be reduced as compared with the case of using a wire or a narrow conductor. Therefore, deterioration of signal transmission characteristics between the source electrodes of the MOSFETs 20a and 20b can be suppressed.

Furthermore, in the configuration according to the first embodiment, the conductors 62 and 63 for coupling the input terminals 90 and 91 and the light emitter 50 are provided immediately below the light emitter 50. Therefore, it is possible to reduce an area for installing electrode pads corresponding to the conductors 62 and 63 on the substrate 10. Further, in the configuration according to the first embodiment, the MOSFETs 20a and 20b and the light receiver 30 are provided at positions not intersecting each other on the XY plane. Therefore, the MOSFETs 20a and 20b and the light receiver 30 and the light emitter 50 can be disposed close to one another in the X direction. In this way, the photo relay device 1 can be downsized.

Moreover, since the configuration according to the first embodiment does not use a wire, the height required by the wire can be reduced, and the thickness of the photo relay device 1 can be reduced. In addition, since a step of coupling the wire becomes unnecessary, the number of steps at the time of manufacturing can be reduced.

The photo relay device according to the first embodiment described above can be variously modified.

For example, a configuration is conceivable in which the conductor 71 is divided into a first portion that is in contact with the electrode 31 of the light receiver 30 and has a flat plate shape extending in the X direction, and a second portion that is in contact with the electrode 32 of the light receiver 30 and has a flat plate shape extending in the X direction. In this case, it is necessary to provide at least two or more conductors 72. At least one of the conductors 72 couples the first portion of the conductor 71 and the conductor 70. At least one of the conductors 72 couples the second portion of the conductor 71 and the conductor 70.

Next, a second embodiment will be described. Hereinafter, a structure different from that of the first embodiment will be mainly described.

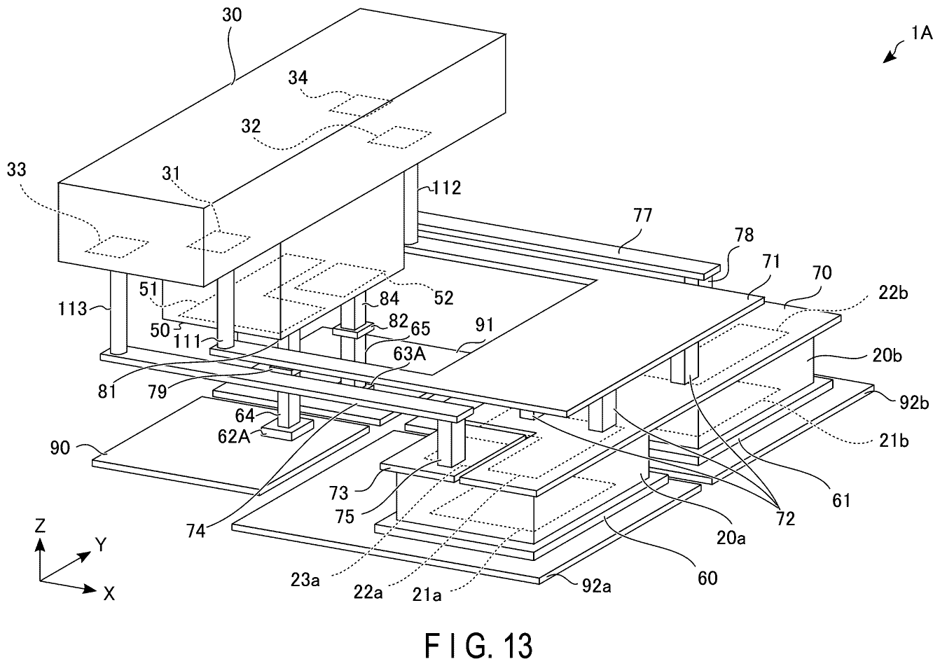

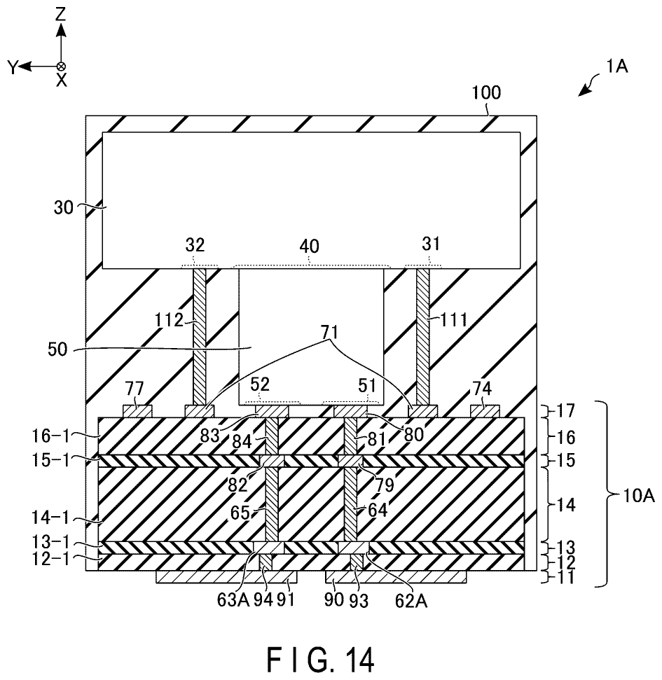

FIG. 13 is a perspective view showing an example of an overall structure of a photo relay device according to the second embodiment. FIG. 14 is a cross-sectional view of a cross section corresponding to FIG. 5 in the first embodiment, showing an example of a cross-sectional structure of the photo relay device according to the second embodiment. A structure of a photo relay device 1A according to the second embodiment will be described with reference to FIGS. 13 and 14.

The photo relay device 1A according to the second embodiment includes a substrate 10A instead of a substrate 10, and further includes conductors 111, 112, and 113 and a conductor 114 (not shown). The substrate 10A includes conductors 62A and 63A instead of conductors 62 and 63 in the substrate 10 in addition to a configuration included in the substrate 10, and further includes conductors 64, 65, 79, 80, 81, 82, 83, and 84.

The substrate 10A includes, for example, a seven-layer structure in which an interconnect layer 11, an insulator layer 12, an interconnect layer 13, an insulator layer 14, an interconnect layer 15, an insulator layer 16, and an interconnect layer 17 are stacked sequentially in an upward direction. The substrate 10A does not include an opening.

The conductors 62A and 63A are provided in the interconnect layer 13. The conductor 62A is in contact with a conductor 93 on a bottom surface and is in contact with the conductor 64 on a top surface. The conductor 63A is in contact with a conductor 94 on a bottom surface and is in contact with the conductor 65 on a top surface. An insulator 13-1 insulates the conductors 60, 61, 62A, and 63A from one another.

The conductors 64 and 65 are provided in the insulator layer 14. The conductor 64 functions as a via extending in a Z direction inside an insulator 14-1 so as to couple the top surface of the conductor 62A and the bottom surface of the conductor 79. The conductor 65 functions as a via extending in the Z direction inside the insulator 14-1 so as to couple the top surface of the conductor 63A and the bottom surface of the conductor 82. The insulator 14-1 insulates the conductors 64 and 65 from each other.

The conductors 79 and 82 are provided in the interconnect layer 15. The conductor 79 is in contact with the conductor 64 on the bottom surface and in contact with the conductor 81 on the top surface. The conductor 82 is in contact with the conductor 65 on the bottom surface and in contact with the conductor 84 on the top surface. An insulator 15-1 insulates the conductors 70, 73, 76, 79, and 82 from one another.

The conductors 81 and 84 are provided in the insulator layer 16. The conductor 81 functions as a via extending in the Z direction inside the insulator 16-1 so as to couple the top surface of the conductor 79 and the bottom surface of the conductor 80. The conductor 84 functions as a via extending in the Z direction inside the insulator 16-1 so as to couple the top surface of the conductor 82 and the bottom surface of the conductor 83. The insulator 16-1 insulates the conductors 72, 75, 78, 81, and 84 from one another.

The conductors 80 and 83 are provided in the interconnect layer 17. The conductor 80 is in contact with the conductor 81 on the bottom surface and in contact with the electrode 51 of the light emitter 50 on the top surface. The conductor 83 is in contact with the conductor 84 on the bottom surface and in contact with the electrode 52 of the light emitter 50 on the top surface.

With the above configuration, the electrode 51 of the light emitter 50 and the input terminal 90 are coupled via the conductors 62A, 64, 79, 80, 81, and 93. In addition, the electrode 52 of the light emitter 50 and the input terminal 91 are coupled via the conductors 63A, 65, 82, 83, 84, and 94.

The conductors 111, 112, 113, and 114 are, for example, metal spacers. The conductor 111 is provided between the electrode 31 of the light receiver 30 and the conductor 71 so as to extend in the Z direction, and couples them. The conductor 112 is provided between the electrode 32 of the light receiver 30 and the conductor 71 so as to extend in the Z direction, and couples them. The conductor 113 is provided between the electrode 33 of the light receiver 30 and the conductor 74 so as to extend in the Z direction, and couples them. The conductor 114 is provided between the electrode 34 of the light receiver 30 and the conductor 77 so as to extend in the Z direction, and couples them. The conductors 111, 112, 113, and 114 fix the substrate 10A and the light receiver 30, and support the light receiver 30.

With the above configuration, the electrodes 31 and 32 of the light receiver and the electrode 22a of the MOSFET 20a and the electrode 22b of the MOSFET 20b are coupled via the conductors 70, 71, and 72 and the conductors 111 and 112. The electrode 33 of the light receiver 30 and the electrode 23a of the MOSFET 20a are coupled via the conductors 73, 74, and 75 and the conductor 113. The electrode 34 of the light receiver 30 and the electrode 23b of the MOSFET 20b are coupled via the conductors 76, 77, and 78 and the conductor 114.

A method for manufacturing the photo relay device according to the second embodiment will be described. First, the substrate 10A in which the MOSFETs 20a and 20b are embedded is formed by substantially the same steps as the steps of forming the substrate 10 shown in FIG. 10 in the first embodiment. Note that the interconnect layer 15 is provided such that the conductors 79 and 82 are coupled to the conductors 64 and 65, respectively.

Thereafter, the light receiver 30 and the light emitter 50 are bonded onto a top surface of the substrate 10A without performing laser processing. Specifically, first, one end of each of the conductors 111, 112, 113, and 114 is joined to the electrodes 31, 32, 33, and 34 of the light receiver 30, respectively. Thereafter, the light receiver 30 and the light emitter 50 joined via an adhesive layer 40 are provided on the top surface of the interconnect layer 17 such that the light emitter 50 corresponds thereto. The electrodes 51 and 52 of the light emitter 50 are joined to the conductors 80 and 83 of the interconnect layer 17, respectively. The other end of each of the conductors 111 and 112 is joined to the conductor 71 of the interconnect layer 17. The other end of each of the conductors 113 and 114 is joined to the conductors 74 and 77 of the interconnect layer 17, respectively.

Note that the step of bonding the light receiver 30 and the light emitter 50 onto the top surface of the substrate 10A is not limited to the above method. For example, the light receiver 30 and the light emitter 50 may be disposed on the substrate 10A, and then the conductors 111, 112, 113, and 114 may be formed. Specifically, first, the light receiver 30 and the light emitter 50 joined via the adhesive layer 40 are provided on the top surface of the interconnect layer 17 such that the light emitter 50 corresponds thereto. The electrodes 51 and 52 of the light emitter 50 are joined to the conductors 80 and 83 of the interconnect layer 17, respectively. Thereafter, the conductors 111, 112, 113, and 114 are provided so as to couple the electrodes 31, 32, 33, and 34 of the light receiver 30 and the conductors 71, 74, and 77 in the interconnect layer 17. One end of the conductor 111 is joined to the electrode 31, and the other end thereof is joined to the conductor 71. One end of the conductor 112 is joined to the electrode 32, and the other end thereof is joined to the conductor 71. One end of the conductor 113 is joined to the electrode 33, and the other end thereof is joined to the conductor 74. One end of the conductor 114 is joined to the electrode 34, and the other end thereof is joined to the conductor 77.

Finally, a portion excluding the lower portion of the structure obtained by the above-described steps is sealed with the sealing resin 100. In this way, the photo relay device 1A is manufactured.

In the configuration according to the second embodiment, similarly to the first embodiment, a length of an open stub can be reduced, transmission characteristics of signals can be improved, and deterioration of the transmission characteristics of the signals due to coupling capacitances and high impedances can be suppressed.

Further, in the configuration according to the second embodiment, similarly to the first embodiment, it is possible to reduce an area for installing electrode pads corresponding to the conductors 62 and 63 on the substrate 10A. Moreover, in the configuration according to the second embodiment, the light emitter 50 is provided at a position not intersecting the substrate 10A on an XY plane. Therefore, the light receiver 30 and the light emitter 50 can be disposed at positions further closer to the MOSFETs 20a and 20b in an X direction. In this way, the photo relay device 1A can be downsized.

In addition, the configuration according to the second embodiment does not include an opening. Therefore, since laser processing for forming the opening becomes unnecessary, the number of steps at the time of manufacturing can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate including a first surface extending in a first direction and a second direction;
a first transistor;
a light receiver;
a light emitter provided on the light receiver;
an input terminal provided on the first surface of the substrate;
a first conductor configured to electrically couple a source electrode of the first transistor and a first electrode of the light receiver;
a second conductor configured to electrically couple a gate electrode of the first transistor and a second electrode of the light receiver; and
a third conductor configured to couple a third electrode of the light emitter and the input terminal, wherein
the light emitter and the input terminal are provided at positions overlapping with each other in a third direction intersecting the first direction and the second direction, and
the third conductor is provided inside the substrate.

2. The semiconductor device according to claim 1, wherein
the input terminal, the substrate, the light emitter, and the light receiver are sequentially disposed in the third direction.

3. The semiconductor device according to claim 1, wherein
a light receiving surface of the light receiver is provided to face a light emitting surface of the light emitter.

4. The semiconductor device according to claim 1, wherein
the substrate further includes a second surface extending in the first direction and the second direction and different from the first surface, and
the first conductor and the second conductor are provided inside the substrate and on the second surface.

5. The semiconductor device according to claim 1, further comprising:
a first output terminal provided on the first surface of the substrate; and
a fourth conductor configured to electrically couple the first output terminal and a drain electrode of the first transistor, wherein
the fourth conductor is provided inside the substrate.

6. The semiconductor device according to claim 1, wherein
the first transistor is provided inside the substrate so as to be embedded in the substrate.

7. The semiconductor device according to claim 4, wherein
the substrate includes an opening recessed in the third direction on the second surface,
the light emitter is provided in the opening of the substrate so as to be aligned with the first transistor in the first direction,
the first electrode of the light receiver is in contact with the first conductor on the second surface of the substrate, and
the second electrode of the light receiver is in contact with the second conductor on the second surface of the substrate.

8. The semiconductor device according to claim 7, wherein
the first transistor is provided inside the substrate so as to be embedded in the substrate, and
the drain electrode of the first transistor and the third electrode of the light emitter are provided at substantially the same position in the third direction.

9. The semiconductor device according to claim 4, wherein
the first conductor and the second conductor further include a portion extending in the third direction outside the substrate, and
the third electrode of the light emitter is in contact with the third conductor on the second surface of the substrate.

10. The semiconductor device according to claim 9, wherein
the portion of the first conductor and the second conductor extending in the third direction outside the substrate includes a conductive spacer.

11. The semiconductor device according to claim 1, further comprising:
a second transistor provided so as to be aligned with the first transistor in the second direction; and
a fifth conductor configured to electrically couple a gate electrode of the second transistor and a fourth electrode of the light receiver, wherein
the first conductor further electrically couples a source electrode of the second transistor to the source electrode of the first transistor and the first electrode of the light receiver.

12. The semiconductor device according to claim 11, wherein
the first conductor has a flat plate shape extending in the first direction and the second direction, and is provided so as to cover the source electrode of the first transistor and the source electrode of the second transistor.

13. The semiconductor device according to claim 11, wherein
the substrate further includes a second surface extending in the first direction and the second direction and different from the first surface, and
the first conductor, the second conductor, and the fifth conductor are provided inside the substrate and on the second surface.

14. The semiconductor device according to claim 11, further comprising:
a second output terminal provided on the first surface of the substrate; and
a sixth conductor configured to electrically couple the second output terminal and a drain electrode of the second transistor, wherein
the sixth conductor is provided inside the substrate.

15. The semiconductor device according to claim 11, wherein
the first transistor and the second transistor are provided inside the substrate so as to be embedded in the substrate.

16. The semiconductor device according to claim 13, wherein
the substrate includes an opening recessed in the third direction on the second surface,
the light emitter is provided in the opening of the substrate so as to be aligned with the first transistor and the second transistor in the first direction,
the first electrode of the light receiver is in contact with the first conductor on the second surface of the substrate,
the second electrode of the light receiver is in contact with the second conductor on the second surface of the substrate, and
the fourth electrode of the light receiver is in contact with the fifth conductor on the second surface of the substrate.

17. The semiconductor device according to claim 16, wherein
the first transistor and the second transistor are provided inside the substrate so as to be embedded in the substrate, and
the drain electrode of the first transistor, the drain electrode of the second transistor, and the third electrode of the light emitter are provided at substantially the same position in the third direction.

18. The semiconductor device according to claim 13, wherein
the first conductor, the second conductor, and the fifth conductor further include a portion extending in the third direction outside the substrate, and
the third electrode of the light emitter is in contact with the third conductor on the second surface of the substrate.

19. The semiconductor device according to claim 18, wherein
the portion of the first conductor, the second conductor, and the fifth conductor extending in the third direction outside the substrate includes a conductive spacer.
